(19) United States
(12) Patent Application Publication
(10) Pub. No.: US 2006/0097807 A1
(43) Pub. Date: May 11, 2006

(54) Hyperfrequency oscillator with very high stability

(75) Inventors: Jean-Claude Mage, Palaiseau (FR); Bruno Marcilhac, Nozay (FR)

Correspondence Address: LOWE HAUPTMAN GILMAN & BERNER, LLP, 1700 DIAGNOSTIC ROAD, SUITE 300, ALEXANDRIA, VA, 22314, US

(73) Assignee: Thales, Neuilly Sur Seine (FR)

(21) Appl. No.: 10/540,921

(22) PCT Filed: Dec. 15, 2003
(86) PCT No.: PCT/EP03/51014

§ 371 Date: Jun. 29, 2005

(30) Foreign Application Priority Data
Dec. 31, 2002 (FR) 02/16903

(51) Int. Cl. H03B 9/14

(52) U.S. Cl. 331/107 DP

(57) ABSTRACT

The oscillator of the invention comprises a one-piece dielectric resonator in the form of a right cylinder frustum hollowed out at mid-height along chords of its cross section, so as to leave a central core and two lateral flanges, the drillholes having symmetry of order N, where N≧4, at least the plane faces of the cylinder being covered with a superconducting material, the resonator being placed in a cryogenic chamber and being connected to an amplifier via optimized couplings, and the tuning of the resonator being done by a magnetic field and a phase loop.

The present invention relates to a microwave oscillator of very high stability.

Signal generation for radar applications, telecommunications and frequency references (such as atomic clocks based on Cs, Rb etc.), and also the developments in digital systems, require oscillators of very high stability that exhibit ever decreasing phase noise.

An oscillator consists of two main components, namely a resonator and an active element or amplifier. The phase noise of oscillators is determined by the combination of the low-frequency noise, the high-frequency noise and the nonlinearities of the active element, the quality factor Q of the resonator and the coupling circuit for coupling between oscillator and active element. The phase noise of oscillators, expressed in the frequency domain, corresponds in the time domain to clock jitter which determines the ultimate precision of all digital signal processing systems and, primarily, analog/digital encoders. The trend in analog and digital systems, in particular the increase in speed and dynamic range of analog/digital converters, is toward a reduction in phase noise of oscillators and the time jitter of clocks.

At the present time, reference oscillators are based on bulk acoustic wave or surface acoustic wave resonators. These resonators are limited, as regards those of highest performance, to frequencies of about 1000 MHz using FBAR (Film Bulk Acoustic-Wave Resonator) technology. Apart from their technological limitations (resonator thickness), acoustic resonators are governed by a fundamental physical law, whereby the product Qf, i.e. the maximum quality factor Q multiplied by the operating frequency f, is a characteristic of the material used. This product may be evaluated by the theory of acoustic loss (an harmonic phonon interactions). Typically, this product is about 10 THz. The quality factor of FBAR-type resonators is thus limited to about 10⁴ for an operating frequency of 1000 GHz.

In practice, it is necessary to generate signals at frequencies very much above 1 GHz. It is therefore necessary to use frequency multipliers. Such an operation degrades the phase noise by at least 20 log N for a multiplication factor N, this resulting from an unavoidable mathematical law.

To achieve the stability performance required for future frequency synthesizers, it will be necessary to use resonators operating at higher frequencies (so as to remove the noise due to the multiplication) and with higher quality factors.

Electromagnetic resonators (metal cavities, dielectric resonators, etc.) allow direct operation at frequencies of several GHz, but their quality factor is limited. For example, for conventional dielectric resonators, a Qf product of 200 THz is obtained, while for sapphire whispering-gallery resonators, at room temperature, a Qf product of 2500 THz is obtained. The phase noise values are thus close to those of multiplied acoustic sources—typically, values of −120 dBc/Hz are obtained at a few kHz from the carrier in the case of the best oscillators.

The limit of current oscillators corresponds to a measurement resolution of analog/digital encoders operating at a frequency of about 1 GHz of 8 encoding bits, which causes a phase jitter of less than 0.3 ps. The systems currently envisaged would require encoders operating at at least 2 GHz with 10-bit resolution, with a phase noise of less than −150 dBc/Hz and with a modulation frequency of 1 kHz. Such performance can be obtained only with resonators having a very high quality factor (Q>10⁶ at 10 GHz for example) combined with oscillator structures that preserve the intrinsic quality of the resonators.

At the present time, the only known solution for increasing the quality factor Q involves oscillators based on cooled electromagnetic resonators. By combining cooled dielectric resonators and superconducting films it is possible to increase the quality factor by two orders of magnitude, i.e., in theory, an increase from 20 to 40 dBc/Hz for the phase noise of the oscillators. However, in practice this improvement is reduced by the sensitivity of the resonators to vibrations and to thermal fluctuations.

The subject of the present invention is a microwave oscillator of very high reference stability, of the resonator type, this resonator exhibiting insignificant sensitivity to vibrations and thermal fluctuations.

The oscillator according to the invention comprises a one-piece dielectric resonator in the form of a right cylinder frustum hollowed out at mid-height along chords of its cross section, so as to leave a central core and two lateral flanges, the drillholes having symmetry of order N, where N≧4, at least the plane faces of the cylinder being covered with a superconducting material, the resonator being placed in a cryogenic chamber and being connected to an amplifier via optimized couplings, and the tuning of the resonator being done by a magnetic field and a phase loop.

The present invention will be more clearly understood on reading the detailed description of several embodiments, given by way of nonlimiting examples and illustrated by the appended drawing in which:

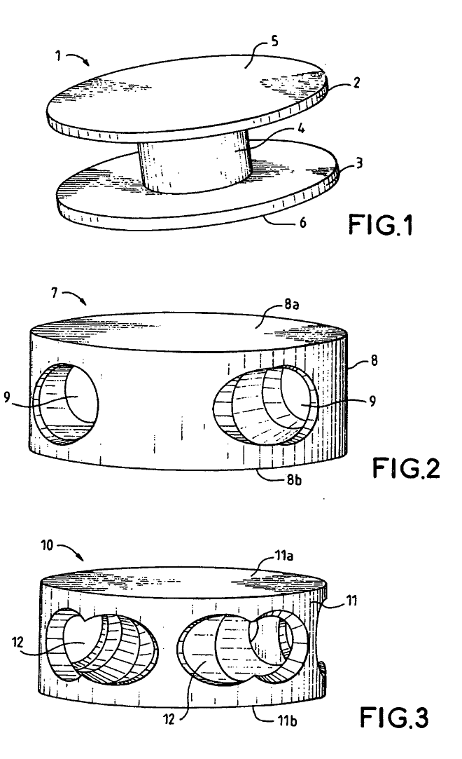

FIGS. 1 to 3 are perspective views of three different embodiments of an oscillator resonator according to the invention;

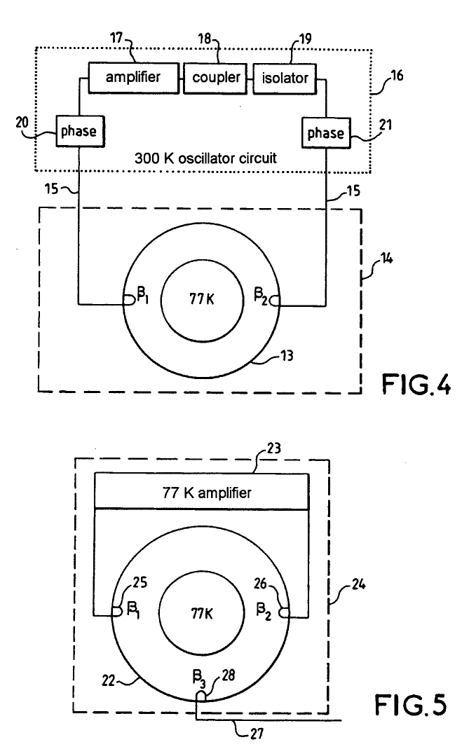

FIGS. 4 and 5 are simplified diagrams of microwave resonator oscillator structures that can be used by the invention; and

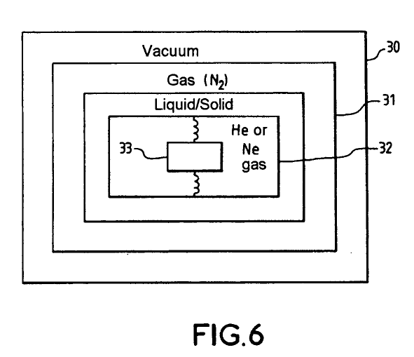

FIG. 6 is a simplified diagram of a triple-chamber cryogenic system used by the invention.

Since one of the essential components of a microwave oscillator is its resonator, and since the stability of this resonator is affected by mechanical strains, the invention produces it in a different manner from that usually employed. The usual structure of a known resonator generally comprises a cavity in the form of a cylinder frustum closed at its two ends by plane walls made of lanthanum aluminate coated on one face with a single-crystal superconducting material, for example Y₁Ba₂Cu₃O₇ containing the actual resonator with its sapphire support and centering foot and two ports for coupling to the cavity. For this purpose, so as to minimize the mechanical strain sensitivity of the resonators, the invention proposes solutions to several undesirable effects in the case of known resonators, these effects being:
the variations in height of the cavity of the resonator, which the invention minimizes by a one-piece (monolithic) resonator structure;
the fluctuations in distance (on the scale of one nanometer) between the superconducting films deposited on a single-crystal substrate forming the plane surfaces of the cavity, which fluctuations are also greatly reduced by the one-piece structure; and
the variation in dielectric constant due to the effect of the strain of the resonator.

The ideal solution would be to be able to deposit the superconducting material on all the faces of the cavity of the resonator. However, as it is impossible for a high-quality film of high-T_{c} (high critical temperature) superconductor to be grown epitaxially on curved surfaces, the invention proposes to produce a monolithic dielectric resonator, with the general shape of a cylinder frustum, appropriately hollowed out, with direct deposition of the superconducting films on the two plane faces of the cavity, before they are machined. Since the electric field is concentrated on the central core, the degradation of the quality factor by the currents induced in the rest of the structure of the resonator is minimized. The constituent material of the resonator is advantageously single-crystal sapphire.

According to a first embodiment of the invention, shown in FIG. 1, the body 1 of the resonator has the form of a cotton reel with symmetry of revolution about its axis. This body essentially comprises two disc-shaped flanges 2, 3 joined together by a central core 4 formed integrally therewith. A superconducting film is deposited on the plane faces 5, 6 of the flanges 2, 3.

The structure 7 shown in FIG. 2 is formed from a dielectric block 8 in the form of a right solid cylinder frustum in which four holes 9 are made, the axes of the holes lying in a plane perpendicular to the axis of the cylinder, halfway between the plane faces of the cylinder frustum. The axes of these holes exhibit symmetry of order 4 with respect to the cylinder axis, leaving behind a large part of the cylindrical wall and a central core. As in the case of the previous structure, a superconducting film 8a, 8b is deposited on the plane faces of the structure 7.

The structure 10 shown in FIG. 3 is formed, like that in FIG. 2, from a dielectric block 11 in the form of a right solid cylinder frustum in which five holes 12 are made, the axes of which lie in a plane perpendicular to the axis of the cylinder, halfway between the plane faces of the cylinder frustum. The axes of these holes exhibit symmetry of order 5 with respect to the cylinder axis, so that a large part of the cylindrical wall and a central core remain. This structure is generally preferred to that of FIG. 2. As in the case of the previous structures, a superconducting film 11a, 11b is deposited on the plane faces of the structure 10.

The structures of FIGS. 1 to 3 allow the phase noise to be very substantially attenuated between 1 and 10 kHz, at which frequencies there is coincidence between the acoustic wavelengths and the dimensions of the resonator cavity. The values predicted by Leeson's theory (in which the quality factor of a cavity with superconducting films may be estimated by the point at which the colored noise rises above the thermal noise floor) then become achievable. Of course, the constituent materials of these structures must have very low dielectric losses and must be compatible with the deposition of superconducting films.

Next, a theoretical approach allows suitable shapes for the resonators to be determined, for each value of the dielectric constant of the constituent material of the actual resonator, in which shapes the compensation effect occurs, that is to say the diameter/height ratio of the cavity at which the frequency change induced by a slight change in the height is equal and opposite to that induced by the change in diameter resulting from the mechanics equations.

To a first approximation, the resonant frequency of the cavity may be calculated in the configuration described by Hakki and Coleman (see: D. Maystre et al., IEEE MTT, 31, pp 844-848, October 1983) by the equation:
k_{rε}J₀(k_{rε}r)/j₁(k_{rε}r)=kᵣ₀Z₀(kᵣ₀r)/Z₁(kᵣ₀r)
in which:
jᵢ is a Bessel function of the first kind, of order i
Zᵢ is a Bessel function of the second kind, of order i
K₀²=k_{z}²+kᵣ₀²
k_{ε}²=k_{z}²+k_{rε}²=εk₀²
k₀=2πf/c
k_{Z}=π/h
r=radius of the central hub
h=height of the resonator
f=resonant frequency
   r and h being related through Young's modulus and Poisson's ratio.

For perfect compensation, the variation in the dielectric constant ε due to mechanical strains should be taken into account.

To a first approximation, the dependency of the constant ε with respect to the volume V may be deduced from the Clausius-Mossotti equation:
(ε−1)/(ε+2)=NαV
where N is the number of molecules per unit volume and α is the polarizability of a molecule.

The volume change may be calculated from Young's modulus and Poisson's ratio.

In the general case, there is no analytical solution, since:
the frequency must be determined case by case by solving Maxwell's equations numerically;
r and h are related through the Navier-Stokes equations between stresses σᵢⱼ and strains eᵢⱼ via the elasticity tensor Cᵢⱼ; and
the variation of the permittivity tensor εᵢⱼ must be calculated as a function of the mechanical strains eᵢⱼ.

The resonant frequency is a function of the diameter D of the central core, of the height h and of the permittivity ε.

The frequency fluctuations df related to the dimensions of the resonator cavity are given by:
df=(∂f/∂D)dD+(∂f/∂h)dh.

Values of the parameters (ε, D, h) exist such that, to a first approximation, df=0 for a free structure. By choosing suitable values of the these parameters it is possible to get round the problem of the resonator strains and to obtain a phase noise close to that according to Leeson's theory.

According to a second important feature of the invention, the structure of the oscillator is optimized by trying to fulfill the following requirements:
suitable coupling between the output of the amplifier of the oscillator and the input of the cavity. For a coupling coefficient of 1, the loaded quality factor of the cavity would be approximately equal to one half of the unloaded quality factor;
suitable coupling between the output of the cavity and the input of the amplifier. The corresponding coupling co-efficient is then equal to the inverse of the amplifier gain;
the electrical loop, comprising the cavity, the amplifier and their link connections, must have a minimum length (the cavity and the amplifier are cooled in the same chamber, as described below with reference to FIG. 5). The electrical length is then 2π, namely π due to the amplifier, π/2 due to the input coupling of the cavity and π/2 due to its output coupling;
the amplifier must be integrated into the cooled chamber of the cavity, as mentioned above;
the amplifier is preferably made in SiGe technology and cooled to very low temperature (the critical temperature of the superconducting films of the cavity). It then has a very low noise (which varies inversely with the working frequency);
the coupling circuit, for coupling between amplifier and cavity, should include a varactor-based phase-regulating device;
feedback control of the total phase of the oscillation loop so as to obtain operation at an optimum point at which the derivative of the phase with respect to frequency is a maximum; and
the signal from the oscillator is preferably output through a third port of the cavity, as described below with reference to FIG. 5. This feature guarantees a noise floor at −180 dBm/Hz by taking off a signal filtered by the resonator itself. This solution is advantageous whenever the unloaded quality factor of the cavity exceeds 10⁶. It is then possible to load the cavity, while still maintaining a high value for the loaded quality factor. Typically, coupling for this output port may be chosen such that the loaded quality factor remains substantially greater than ⅓ of the unloaded quality factor.

FIG. 4 shows a first possible embodiment of an oscillator with a cooled cavity. The cavity 13 with superconducting films is cooled down to a very low temperature, for example 77 K, in a chamber 14. It is connected via cables 15 having an impedance of 50 ohms to an amplifier device 16 which is at room temperature (around 300 K). The amplifier device 16 conventionally comprises an amplifier circuit 17 followed by a coupler 18 and an isolator 19, and it includes two tunable phase shifters 20, 21 that connect the elements 17 to 19 to the cables 15. This embodiment requires relatively long connecting cables (they introduce a phase shift of 2kπ, where k is very much greater than 1). The cables have a high temperature gradient. Since one of their ends is at 72 K and the other at 300 K, these cables may generate noise, and the stability of the oscillator is not excellent.

For these reasons, the invention proposes using the structure of FIG. 5. In this structure, the cavity 22 and the amplifier 23 are placed in the same chamber 24 cooled for example to 77 K. The amplifier is connected to two coupling ports 25, 26 of the cavity via very short links, which means that the 2kπ phase shift between the input and the output of the cavity is small, k being minimal. It should be noted that the signal output 27 is at a third coupling port 28. The amplifier 23 may have a specific topology appropriate to its being mounted in the chamber 24, as close as possible to the cavity, and it is easy to match the cavity and amplifier impedances. Since this structure includes no tunable phase shifters, the fine adjustment of the phase shift is less easy to achieve than in the case of the structure of FIG. 4. However, the preferred structure of the invention is that of FIG. 5, owing to its many advantages over that of FIG. 4.

To ensure that the oscillator is provided with effective and stable cooling, with minimal vibrations, the invention employs a triple chamber 29, as shown diagrammatically in FIG. 6. This triple chamber comprises, from the outside inward, a first, vacuum chamber 30, of the Dewar vessel type, having a thermal insulation role, which contains a second, low-pressure (1 bar, at room temperature, for example) chamber 31 filled with a gas that can liquefy or solidify at the operating temperature (for example nitrogen or argon), this second chamber containing the third chamber 32, which is a sealed case containing helium or neon at very low temperature (for example 73 K) and contains the oscillator 33 of the invention.

In the second chamber, the residual gas pressure is slaved in order to precisely control the temperature of the chamber 32 by evaporation and sublimation of the gas, which condenses as a liquid or solid film on the external surface of the case 32. The gas contained in the chamber 32 must remain in the gaseous phase at the temperature within this chamber, so as to ensure temperature uniformity throughout this chamber and to avoid any condensation on the constituents of the oscillator (any condensation would introduce losses into the circuits and would induce a frequency shift). The cooling in the chamber 32 is achieved with minimal vibration, advantageously by a pulsed tube and circulation of the gas (gaseous helium or neon). A thermal bridge is formed between the chamber 32 and the oscillator by means of a flexible metal braid, for example made of copper. The oscillator is suspended inside the case 32 by a suspension system that transmits the minimum possible vibration to it. This suspension system comprises for example, in a manner known per se, suspension cables with non-resonant springs and weights.

1. A microwave oscillator of very high stability, comprising:
a one-piece dielectric resonator in the form of a right cylinder frustum hollowed out at mid-height along chords of its cross section, so as to leave a central core and two lateral flanges, and having drillholes having symmetry of order N, where N≧4, at least plane faces of the cylinder being covered with a superconducting material, the resonator being placed in a cryogenic chamber and being connected to an amplifier via optimized couplings, and the tuning of the resonator being done by a magnetic field and a phase loop.

2. The oscillator as claimed in claim 1, wherein the resonator is placed in a triple chamber comprising a first chamber for vacuum insulation, a second chamber filled with a gas that can liquefy or solidify at the operating temperature of the resonator, and a third chamber filled with a gas that remains gaseous at said operating temperature.

3. The oscillator as claimed in claim 1, wherein the amplifier is placed in the same cryogenic chamber as the resonator.

4. The oscillator as claimed in claim 1, wherein, when the cavity has two coupling ports for connecting the cavity to the amplifier, the signal is output at a third coupling port of the cavity.

5. The oscillator as claimed in claim 1, wherein the resonator is made of single-crystal sapphire.

6. The oscillator as claimed in claim 2, wherein the amplifier is placed in the same cryogenic chamber as the resonator.

7. The oscillator as claimed in claim 2, wherein when the cavity has two coupling ports for connecting it to the amplifier, the signal is output at a third coupling port of the cavity.

8. The oscillator as claimed in claim 3, wherein when the cavity has two coupling ports for connecting it to the amplifier, the signal is output at a third coupling port of the cavity.

9. The oscillator as claimed in claim 2, wherein the resonator is made of single-crystal sapphire.

10. The oscillator as claimed in claim 3, wherein the resonator is made of single-crystal sapphire.

11. The oscillator as claimed in claim 4, wherein the resonator is made of single-crystal sapphire.
